(19) United States
(12) Patent Application Publication
(10) Pub. No.: US 2025/0210343 A1
(43) Pub. Date: Jun. 26, 2025

(54) TEMPERATURE CONTROL MODULE FOR A FURNACE REACTOR AND METHOD OF CONTROLLING TEMPERATURE OF A FURNACE REACTOR

(71) Applicant: ASM IP Holding B.V., Almere (NL)

(72) Inventors: Marina Mariano, Leuven (BE); Kelly Houben, Lubbeek (BE); Patricio Eduardo Romero, Wilsele (BE)

(21) Appl. No.: 18/983,512

(22) Filed: Dec. 17, 2024

Related U.S. Application Data
(60) Provisional application No. 63/612,895, filed on Dec. 20, 2023.

(51) Int. Cl. H01L 21/02; C23C 16/34; C23C 16/44; C23C 16/458; C23C 16/52; H01L 21/673

(52) U.S. Cl. CPC H01L 21/0217; C23C 16/345; C23C 16/4408; C23C 16/4585; C23C 16/52; H01L 21/0228; H01L 21/67303

(57) ABSTRACT

A furnace system for processing substrates is disclosed. The furnace system comprises a process tube arranged for receiving one or more substrates supported on a wafer boat; one or more heating elements for heating the process tube; a process gas flow source for providing flow of process gas into the process tube; a purge gas flow source for providing flow of purge gas into the process tube; and a temperature control module operably connected to the one or more heating elements. The temperature control module is configured to perform the following steps, after a deposition cycle having a maximum process temperature has taken place in the process tube: causing the process tube temperature to be decreased to a second temperature less than the maximum process temperature; and, after a purge dwell time, causing the process tube temperature to be increased to a third temperature greater than the maximum process temperature.

### CROSS-REFERENCE TO RELATED APPLICATION(S)

This application claims the benefit of U.S. Provisional Application 63/612,895 filed on Dec. 20, 2023, the entire contents of which are incorporated herein by reference.

### FIELD OF INVENTION

The present invention relates generally to semiconductor processing and, more particularly, to the temperature control of a furnace reactor.

### BACKGROUND OF THE DISCLOSURE

In a vertical furnace reactor, wafers can be batch processed by loading a number of wafers into a boat and inserting the boat into the reactor process chamber. During a deposition cycle taking place in the process chamber, such as a low pressure chemical vapor deposition (LPCVD) process to form silicon nitride, one or more layers of material are formed on the wafers. In addition, material can be deposited on the liner of the process chamber. As this liner layer accumulates, the probability of particle contamination by release of particles from the liner layer onto wafers in the process chamber increases. The liner layer may also trap process byproducts which can be released onto the wafers, causing further contamination.

It will be appreciated that particle formation on the wafers is undesirable because the particles can detrimentally affect the performance of semiconductor devices formed on the wafers.

Consequently, there is a need for a substrate processing systems and methods that minimize particle formation during semiconductor substrate processing.

### SUMMARY OF THE DISCLOSURE

According to a first embodiment of the present invention there is provided A furnace system for processing substrates comprising a process tube arranged for receiving one or more substrates supported on a wafer boat; one or more heating elements for heating the process tube; a process gas flow source for providing a flow of process gas into the process tube; a purge gas flow source for providing a flow of purge gas into the process tube; and a temperature control module operably connected to the one or more heating elements, wherein the temperature control module is configured to perform the following steps, after a deposition cycle having a maximum process temperature T1 has taken place in the process tube: causing the process tube temperature to be decreased to a second temperature T2 less than the maximum process temperature T1; and after a purge dwell time, causing the process tube temperature to be increased to a third temperature T3 greater than the maximum process temperature T1.

It is an advantage of embodiments of the present invention that particle contamination can be reduced. It is an advantage of embodiments of the present invention that process byproducts trapped in the liner layer can be removed. It is an advantage of embodiments of the present invention that after application of the temperature increase and decrease according to the first embodiment, a large number of deposition cycles for example a number sufficient to deposit a layer of material 4000 Å thick or even 6000 Å or 8000 Å thick can be carried out before a subsequent application of the temperature protocol according to the first embodiment is needed.

Causing the process tube temperature to be decreased to the second temperature may comprise causing power to the heating elements to be substantially turned off.

Causing the process tube temperature to be decreased to the second temperature may comprise causing a wafer boat to be inserted into the process tube. The wafer boat inserted into the process tube to cause the process tube temperature to be decreased may be empty. The wafer boat inserted into the process tube to cause the process tube temperature to be decreased may contain one or more wafers.

Causing the process tube temperature to be decreased to the second temperature may comprise causing a cold gas to be flowed into the process tube.

Causing the process tube temperature to be decreased to the second temperature may comprise causing a fan system to blow cold air onto the heating elements.

The system may comprise a water-cooling system arranged and configured to cool the one or more heating elements. Causing the process tube temperature to be decreased to the second temperature may comprise causing the water-cooling system to be activated.

The third temperature T3 may be substantially equal to a maximum safe operating temperature of the process tube.

Causing the process tube temperature to be increased to the third temperature may comprise causing the process tube temperature to be ramped up. The temperature ramp rate may be the maximum ramp rate of which the reactor is capable.

The purge dwell time may be chosen to be a sufficient time for the process tube to be substantially purged one time. The purge dwell time may be chosen to be a sufficient time for the process tube to be substantially purged more than once. The purge dwell time may be chosen to be a sufficient time for the process tube to be substantially purged three times.

The temperature control module may be configured to maintain the process tube at the third temperature T3 for a further purge dwell time. The further purge dwell time may be chosen to be a sufficient time for the process tube to be substantially purged one time. The further purge dwell time may be chosen to be a sufficient time for the process tube to be substantially purged more than once. The further purge dwell time may be chosen to be a sufficient time for the process tube to be substantially purged three times. The temperature control module may be further configured to cause the process tube temperature to be decreased to a standby temperature after the further purge dwell time.

The second temperature T2 may be less than about 500 C.

The third temperature T3 may be greater than about 770 C.

The temperature control module may be configured such that the described steps are performed after receiving a trigger signal indicating that a predetermined number of deposition cycles has taken place. The temperature control module may be configured to count a number of deposition cycles and to implement the described steps after a predetermined number of deposition cycles has taken place.

The predetermined number of cycles may be chosen to be a number such that a layer of material greater than 4000 Å thick is deposited. It will be understood that the layer thickness may be distributed over multiple wafer deposition cycles and does not necessarily refer to depositing a single layer of 4000 Å on a single wafer.

The deposition cycle may be a process for depositing silicon nitride.

According to a second aspect of the present invention there is provided a method for semiconductor processing in a vertical furnace, the method comprising the steps of performing at least one deposition cycle in a process tube of the vertical furnace, the at least one deposition cycle having a maximum process temperature T1; causing the process tube temperature to be decreased to a second temperature T2 less than the maximum process temperature T1; waiting a purge dwell time; and increasing the process tube temperature to a third temperature T3 greater than the maximum process temperature T1.

Causing the process tube temperature to be decreased to the second temperature may comprise causing power to the heating elements to be substantially turned off.

Causing the process tube temperature to be decreased to the second temperature may comprise causing a wafer boat to be inserted into the process tube. The wafer boat inserted into the process tube to cause the process tube temperature to be decreased may be empty. The wafer boat inserted into the process tube to cause the process tube temperature to be decreased may contain one or more wafers.

Causing the process tube temperature to be decreased to the second temperature may comprise causing a cold gas to be flowed into the process tube.

Causing the process tube temperature to be decreased to the second temperature may comprise causing a fan system to blow cold air onto the heating elements.

The system in which the method according to the second embodiment is implemented may comprise a water-cooling system arranged and configured to cool the one or more heating elements. Causing the process tube temperature to be decreased to the second temperature may comprise causing the water-cooling system to be activated.

The third temperature T3 may be substantially equal to a maximum safe operating temperature of the process tube.

Causing the process tube temperature to be increased to the third temperature may comprise causing the process tube temperature to be ramped up. The temperature ramp rate may be the maximum ramp rate of which the reactor is capable.

The purge dwell time may be chosen to be a sufficient time for the process tube to be substantially purged one time. The purge dwell time may be chosen to be a sufficient time for the process tube to be substantially purged more than once. The purge dwell time may be chosen to be a sufficient time for the process tube to be substantially purged three times.

The process tube temperature may be maintained at the third temperature T3 for a further purge dwell time. The further purge dwell time may be chosen to be a sufficient time for the process tube to be substantially purged one time. The further purge dwell time may be chosen to be a sufficient time for the process tube to be substantially purged more than once. The further purge dwell time may be chosen to be a sufficient time for the process tube to be substantially purged three times. The process tube temperature may be caused to decrease to a standby temperature after the further purge dwell time.

The second temperature T2 may be less than about 500 C.

The third temperature T3 may be greater than about 770 C.

The described steps may be performed after receiving a trigger signal indicating that a predetermined number of deposition cycles has taken place. A number of deposition cycles may be counted and tracked and the described steps may be implemented after a predetermined number of deposition cycles has taken place.

The predetermined number of cycles may be chosen to be a number such that a layer of material greater than 4000 Å thick is deposited. It will be understood that the layer thickness may be distributed over multiple wafer deposition cycles and does not necessarily refer to depositing a single layer of 4000 Å on a single wafer.

The deposition cycle may be a process for depositing silicon nitride.

This summary is provided to introduce a selection of concepts in a simplified form. These concepts are described in further detail in the detailed description of example embodiments of the disclosure below. This summary is not intended to identify key features or essential features of the claimed subject matter, nor is it intended to be used to limit the scope of the claimed subject matter.

### BRIEF DESCRIPTION OF THE DRAWING FIGURES

Certain embodiments of the present invention will now be described, by way of example, with reference to the accompanying drawings, in which:

FIG. 1 is a schematic cross-section of a furnace system according to embodiments of the present invention;

FIG. 2 is a flow chart showing steps of a method according to embodiments of the present invention;

FIG. 3 shows process tube temperature variation with time during a temperature control protocol implemented according to embodiments of the present invention;

FIG. 4 is a plot of defect count on a selection of wafers for a series of deposition cycles of silicon nitride; after the first, third, and ninth deposition cycle a temperature control protocol according to embodiments of the present invention is carried out.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION OF EXEMPLARY EMBODIMENTS

Although certain embodiments and examples are disclosed below, it will be understood by those in the art that the invention extends beyond the specifically disclosed embodiments and/or uses of the invention and obvious modifications and equivalents thereof. Thus, it is intended that the scope of the invention disclosed should not be limited by the particular disclosed embodiments described below. The illustrations presented herein are not meant to be actual views of any particular material, structure, or device, but are merely idealized representations that are used to describe embodiments of the disclosure.

As used herein, the term “substrate” or “wafer” may refer to any underlying material or materials that may be used, or upon which, a device, a circuit, or a film may be formed. The term “semiconductor device structure” may refer to any portion of a processed, or partially processed, semiconductor structure that is, includes, or defines at least a portion of an active or passive component of a semiconductor device to be formed on or in a semiconductor substrate. Semiconductor substrates can be processed in batches in vertical furnaces. An example of such processing is the deposition of layers of various materials on the substrates. Some of the process may be based on chlorides and ammonia for example.

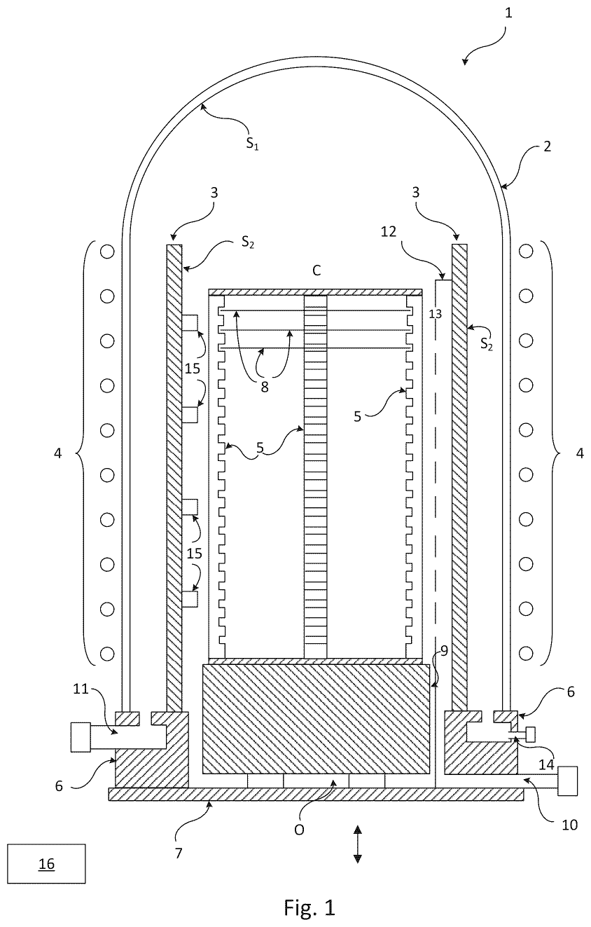

Referring to FIG. 1, a furnace system 1 is shown in cross section. The furnace system 1 includes an outer reaction tube 2 which is generally bell jar shaped and a process tube or liner 3 disposed within the outer reaction tube 2. The process tube 3 is illustrated in FIG. 1 as open ended but may in some embodiments be closed off at the upper end. The process tube or liner 3 can be considered to function as an inner reaction tube.

The outer reaction tube 2 is surrounded by heating means, such as one or more thermally resistive heating coils 4 powered by an electrical power supply (not shown). The heating means provides heat to the outer reaction tube which subsequently causes the interior volume I of the outer reaction tube to be heated, including the process tube 3. In some embodiments, a water cooling system (not shown) is provided for cooling the heating coils. In some embodiments, a fan system (not shown) is provided for cooling the heating coils. The coil cooling systems can help to provide a steeper rate of decrease of temperature of the process tube 3 when power to the heating coils is turned off. Both the outer reaction tube 2 and the liner 3 may be made of quartz, silicon carbide, silicon or another suitable heat resistant material.

In the embodiment shown in FIG. 1 the liner 3 defines a reaction chamber C in which a wafer boat 5 is receivable. Both the outer reaction tube 2 and the liner 3 may be supported at their lower end on a flange 6 for partially closing an open end of the liner 3. The flange may be made of stainless steel. The wafer boat 5 may enter and/or exit the reaction chamber C via a central furnace opening O provided in the flange 6. A vertically movably arranged door 7 may be configured to close off the opening O in the flange 6 and may be configured to support the wafer boat 5. The wafer boat 5 is configured to support wafers 8. The wafer boat 5 may sometimes be inserted into the chamber while empty i.e. not supporting any wafers 8. The wafers 8 may in some cases be dummy wafers which are not intended to be used for further manufacture.

The door 7 may be provided with a pedestal 9. The pedestal 9 may be rotated to have the wafer boat 5 in the inner space rotating. Under the lowest wafer in the boat 5 a flow space may be provided to prevent the flow of reaction gas between the wafers 8 in the boat.

The flange 6 comprises a gas inlet 10 to provide a gas, for example a reaction gas to the reaction chamber C; and a gas exhaust duct 11 to remove gas from the inner space. The gas inlet 10 may be provided with an injector 12 constructed and arranged within the assembly to extend vertically into the inner space I along the substantial cylindrical wall of the liner 3 towards the higher end and comprising injector openings 13 to inject gas in the inner space C. In some embodiments, the injector 12 is not provided and the gas flows upwards from the inlet 10 into the chamber C without its flow being directed by an injector 12.

The assembly may be provided with a purge gas inlet 14 mounted on the flange for providing a purge gas to the reaction chamber C and the process tube 3. The purge gas inlet may optionally be provided with a purge gas injector (not shown) extending vertically along the outer surface of the cylindrical wall of the liner 2 from the flange 3 towards the top end of the liner. In some embodiments, the purge gas injector is not provided and the purge gas flows upwards from the purge gas inlet 14 into the chamber C without its flow being directed by a purge gas injector. In some embodiments, the purge gas inlet 14 is not provided and the gas inlet 10 is configured to provide both a process gas flow source for flowing a process gas into the process tube and a purge gas flow source for flowing a purge gas into the process tube 3. For example, the gas inlet 10 may be coupled to a valve (not shown) coupled to a source of process gas and a source of purge gas, where the valve is configured to adapt at least a configuration in which only the process gas is allowed to flow through the gas inlet 10 and a configuration in which only the purge gas is allowed to flow through the gas inlet 10.

One or more thermocouples 15 are provided within the process tube 3 for measuring the temperature inside the process tube 3. This temperature is referred to herein as the process tube temperature. The thermocouples 15 may be provided each within a different heating zone of the chamber C corresponding to a respective heating element 4. It will be understood by the skilled person that various apparatus/methods for measuring the process tube temperature are known and the present invention is not limited to the thermocouple arrangement described in relation to FIG. 1. The thermocouple(s) 15 and the heating elements 4 are directly or indirectly connected to a temperature control module 16. For example, in some embodiments the thermocouples 15 may be connected to a data processing module (not shown) separate from the temperature control module 16, wherein the data processing module is configured to receive raw data from the thermocouples 15, convert this data to temperature values, and provide the temperature values to the temperature control module 15. In such an embodiment the temperature control module 16 indirectly receives data from the thermocouples 15. In some embodiments, the temperature control module 15 may receive raw data directly from the thermocouples 15 and may convert this data to temperature values internally within the temperature control module 15.

The temperature control module 16 is operably connected to the one or more heating elements 4. The connection may be direct or indirect. For example, in some embodiments, the temperature control module 16 may have a direct connection to the power supply for the heating elements 4 such that a control signal for the heating elements 4, for example to implement the thermal shock described further herein, sent as output from the temperature control module 16 is directly provided to the power supply. In some embodiments, the temperature control module 16 may have an indirect connection to the power supply for the heating elements 4 such that data indicative of a target temperature setpoint is output from the temperature control module to an intermediate control module or other system component (not shown) which is configured to receive such data as input and provide a corresponding input to the heating elements 4. The data indicative of a target temperature setpoint may be, for example, a temperature value, a power value, or other value which corresponds to the target temperature of the process tube.

By way of example, a typical deposition cycle may proceed as follows. The door 7 is moved downwards and a wafer boat 5 containing wafers 8 to be processed is placed on the pedestal. The door 7 is moved upwards and positioned such that the outer reaction tube 2 is closed on the lower end. A series of temperature changes (for example by controlling power provided to the heating elements, or other temperature control elements such as water cooling system), process gas flows for forming layers of material on the wafers 8, and purge gas flows for removing excess process gas and formed reaction by-products, is carried out depending on the desired wafer characteristics. In one embodiment, the deposition cycle is a process for depositing silicon nitride on the wafers 8, for example using dichlorosilane and ammonia as precursors or hexachlorodisilane and ammonia. The skilled person will understand that other deposition processes are possible in the furnace system. At the end of a deposition cycle the temperature is returned to a standby temperature and the wafer boat 5 is removed from the reaction tube 2 via the opening O. The maximum temperature of the process tube 3 during a deposition cycle is referred to herein as T₁. The maximum temperature of a series of deposition cycles, each having different maximum temperatures themselves, is the largest of the individual cycle maximum temperatures.

In addition to forming layers of material on the wafers 8, the process gas forms a material layer on the inner surface S₁ of the outer reaction tube 2 and the surface S₂ of the liner 3 during the deposition cycles. This material layer is a source of particle contamination. Embodiments of the present invention aim to reduce this particle contamination by controlling the temperature of the process tube 3 according to a temperature control protocol comprising of first subjecting the reaction tube 2 chamber to a thermal shock (stage 1) thereby decreasing the process tube temperature to a temperature T₂ less than the maximum process temperature T₁, and then raising the process chamber temperature to a third temperature T₃ greater than the maximum process temperature T₁ (stage 2).

Without being bound by theory, it is believed that the thermal shock in stage 1, which decreases the process tube temperature to less than the maximum temperature in the process tube during the preceding deposition cycle(s), induces relaxation of the stress in and causes cracking of the material layer deposited on the surface of the process tube 3 during the deposition cycle(s). This generates particles but, as no wafers (or only dummy wafers) are present in the process tube, wafers intended for further processing into end products are not contaminated by these particles. The particles are exhausted by flowing a purge gas through the chamber C and/or by evacuation of the chamber C. Then, during stage 2, it is believed that by heating the process tube to a temperature T₃ higher than the maximum process temperature, T₁ byproducts trapped within, on, or under the material layer are released and can be exhausted by flowing a purge gas and/or by evacuation of the process tube. Thus the particle contamination after stage 2 is further reduced in addition to the reduction achieved by stage 1, resulting in a cleaner atmosphere within the process tube 3 for future deposition cycles.

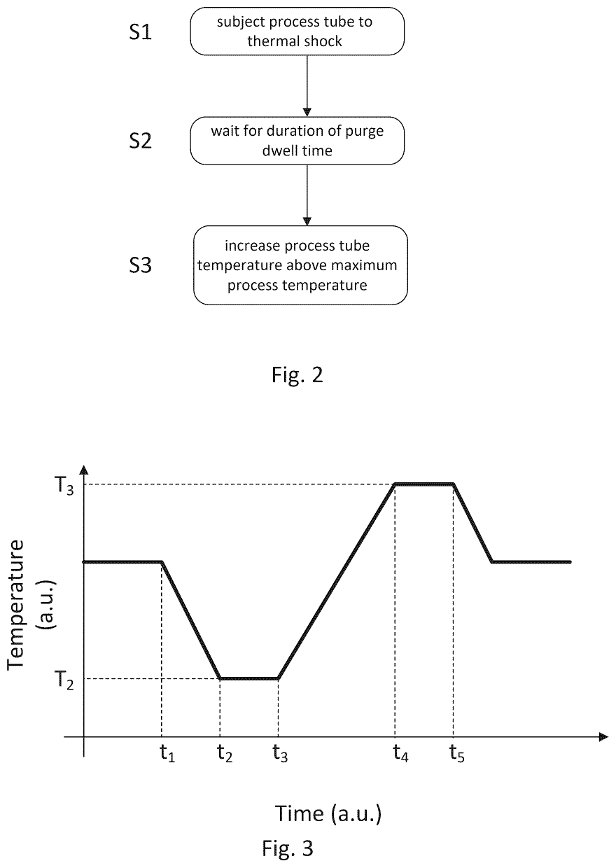

In an example embodiment, referring to FIGS. 2 and 3, the temperature control protocol proceeds as follows. After a deposition cycle has ended and the wafer boat 5 containing processed wafers 8 has been removed from the process tube 3, beginning at time t₁ the process tube 3 is subjected to a thermal shock in which the process tube 3 is subjected to a large temperature change (decrease) in a relatively short time. The temperature is decreased at least to a temperature T₂ less than the maximum process temperature T₁ of the preceding deposition cycle(s) (step S₁). At time t₂, after the temperature drop of the process tube, a wait time from t₂ until t₃ is observed during which the temperature of the process tube may continue to decrease (step S₂). During this wait time, or purge dwell time, the process tube is purged using a purge gas. Examples of suitable purge gases include, but are not limited to, nitrogen, nitrogen ammonia, pure ammonia. It will be understood by the skilled person that other suitable purge gases may be used. At the end of the purge dwell time, t₃, the process tube temperature is rapidly increased to a temperature T₃ which is greater than the maximum process temperature (step S3). Once temperature T₃ is reached, at time t₄, the process tube is maintained at this temperature T₃ for a further wait time, or purge dwell time, from t₄ until t₅, during which period the process tube is again purged using a purge gas. Examples of suitable purge gases include, but are not limited to, nitrogen, nitrogen ammonia, pure ammonia. It will be understood by the skilled person that other suitable purge gases may be used. After the wait time, at time t₅, the process tube temperature may be returned to a standby temperature in preparation for further operation.

The temperature control protocol may be implemented by programming the temperature control module 16 which is operably connected to at least the heating elements 4. In some embodiments, the change in temperature of the process tube 3 can be caused solely by controlling the power supplied to the heating elements 4. In some embodiments, additional optional elements of the furnace system 1 may be used to influence the temperature of the process tube 3 and the temperature control module 16 may in such embodiments be operably connected to those additional element(s). Such additional elements may comprise one or more of a water cooling system for cooling the heating coils 4, a purge gas flow system for supplying cold gas into the process tube 3, a wafer boat handling system for inserting/removing a wafer boat 5 into/from the process tube 3, a wafer handling system for inserting/removing wafers 8 into/from a wafer boat 5, a fan system for blowing cold air onto the heating elements 4. The temperature control module 16 may be directly or indirectly connected to one or more of these additional elements. For example, in some embodiments, the temperature control module 16 may send one or more signals directly to one or more of these additional elements for controlling their operation. In some embodiments, the temperature control module 16 may send one or more signals to an intermediate element such as a central control module configured to control or send control signals to the additional elements.

For example, in one embodiment, the thermal shock may be caused by turning off the power to the heating coils 4. In another embodiment, the thermal shock may be caused by turning off the power to the heating coils 4 and causing a water cooling system for the heating coils to be activated. Use of a water cooling system for the heating coils 4 can provide a greater rate of decrease of the process tube temperature, decreasing the total time needed for the temperature control protocol.

In a further embodiment, the thermal shock may be caused by inserting an empty wafer boat into the process tube 3. The cold mass of the wafer boat may increase the cooldown rate of the process tube 3. In another embodiment, the thermal shock may be caused by inserting a wafer boat containing dummy wafers into the process tube 3. The cold mass of the wafer boat plus dummy wafers may further increase the cooldown rate of the process tube 3; the dummy wafers can be subjected to potential particle contamination without concern regarding their future usability. In some embodiments, the thermal shock may be caused by inserting a cold mass, such as a cold solid cylinder with dimensions similar to that of the wafer boat into the process tube 3. The solid mass may provide a faster cooldown of the process tube 3 in comparison with the wafer boat. The wafer boat (with or without wafers) or the cold mass may be inserted into the process tube 3 at or close to the maximum speed allowable by the furnace system 1, so as to bring the boat or cold mass into close proximity with the process tube 3 promptly.

In some embodiments, the thermal shock may be caused by flowing a cold gas into the process tube 3, for example through one or both of the gas inlets 10, 14 or through one or more separate gas inlets (not shown). In some embodiments, the thermal shock may be caused by causing a fan system for blowing cold air onto the heating elements 4 to be activated.

In some embodiments, it is preferred that the decrease in temperature is implemented in a very short time period such that the total time for the temperature control protocol is minimized. Therefore, the method of implementing the thermal shock may be chosen as that which causes the fastest decrease in temperature for the system concerned. For example, in a system without water cooling or cold purge gas capabilities, the thermal shock may be caused by turning off power to the heating coils and inserting a wafer boat containing dummy wafers into the process tube.

The above-described approaches for causing the thermal shock may be combined in any combination. For example, but not by way of limitation, in one embodiment, the temperature control module may be configured to cause the thermal shock by turning off power to the heating coils and causing an empty wafer boat to be inserted into the process tube. In another example embodiment, the temperature control module may be configured to cause the thermal shock by turning off power to the heating coils, causing a water cooling system for the heating coils to be activated, and causing a wafer boat containing dummy wafers to be inserted into the process tube.

Once the thermal shock has been applied to the process tube and the process tube temperature has decreased to a value less than the maximum process temperature, a wait time is observed by the temperature control module during which the process tube 3 is purged using a purge gas. The wait time may begin once the process tube 3 has dropped below the maximum process temperature. In some embodiments, the wait time begins once the process tube 3 has dropped below a predetermined temperature which is much less than the maximum process temperature. For example, for a silicon nitride deposition cycle having a maximum process temperature of 770 C, the wait time may begin once the process tube temperature is, for example, less than 700 C, less than 500 C, less than 350 C. It will be understood that the process tube temperature may continue to decrease during the wait time.

During the purge wait time, the process tube 3 is purged using a purge gas, which can help to remove from the process chamber particles released by cracking of the layer of material deposited on the surface of the process tube 3 induced by the thermal shock. In some embodiments, a single purge cycle may be implemented, to substantially purge the process tube one time. In some embodiments, more than one purge cycle may be implemented, for example two or three purge cycles. In some embodiments, no more than three purge cycles may be implemented. The number of purge cycles may be chosen to balance on the one hand the need to evacuate particles, such as those thought to be released from the liner layer during the thermal shock stage, from the process chamber 2, and the need to minimize the duration of the temperature control protocol in order to maximize system time available for deposition cycles.

After the purge wait time, the process tube temperature is increased to a third temperature T₃ which is greater than the maximum process temperature T₁. The third temperature T₃ may be for example the maximum safe temperature of which the reactor is capable. The temperature control module 16 may implement this temperature increase by causing the power to the heating elements 4 to be turned on. The temperature control module 16 may cause any cooling subsystems present, such as a water cooling system or a fan system for the heater coils, to be turned off when the power to the heating elements 4 is turned on. The temperature increase may be a ramped temperature increase in which the temperature is increased by a set amount per unit time, which amount may be limited by the system configuration or materials. In some embodiments, the temperature ramp may be chosen to be the fastest ramp possible for the furnace system 1 without causing damage.

Once the third temperature T₃ has been reached, a further wait time is observed by the temperature control module 16. During the further purge wait time, the process chamber 2 is purged using a purge gas, which can help to remove from the process chamber 2 any byproducts trapped by the layer of material deposited on the process tube 3, as well as any remaining particles released by thermal shock-induced cracking of the layer of material deposited in the process tube 3. In some embodiments, a single purge cycle may be implemented, to substantially purge the process tube one time. In some embodiments, more than one purge cycle may be implemented, for example two or three purge cycles. In some embodiments, no more than three purge cycles may be implemented. The number of purge cycles may be chosen to balance on the one hand the need to evacuate particles, such as those thought to be released from the liner layer during the thermal shock stage, from the process chamber 2, and the need to minimize the duration of the temperature control protocol in order to maximize system time available for deposition cycles. In some embodiments, after the further wait time, the temperature of the process tube 3 is returned to a standby temperature.

The reduction of particle contamination resulting from applying the temperature control protocol described herein allows for multiple deposition cycles to be carried out consecutively before subsequent implementation of the temperature control protocol. For example, the temperature control protocol may be applied every N cycles, where N is the number of cycles needed to deposit a layer of material at least 4000 Å thick, at least 6000 Å or at least 8000 Å thick. The temperature control module 16 may be configured to receive a “trigger” signal from a central control module indicating that the temperature control protocol is to be implemented. The temperature control module 16 may be configured to apply the temperature control protocol every N deposition cycles without receiving such a trigger signal.

The temperature control module 16 may be implemented in hardware and/or in software. The temperature control module 16 may be (physically) part of a central control module or may be (physically) separate from and in communication with a central control module. The temperature control module 16 may comprise a memory for storing instructions for performing a temperature control protocol according to embodiments described herein. The temperature control module may comprise one or more input ports for receiving data. The input data may include for example temperature data from one or more thermocouples or from another control element of the furnace system for example a central control module. The input data may include for example data indicating that a deposition cycle has been completed, optionally indicating one or more properties of the cycle such as process tube temperatures, layer thicknesses, or other parameters. The input data may include for example data or a signal instructing the temperature control module to implement a temperature control protocol according to embodiments of the present invention. The temperature control module may comprise one or more output ports for sending data. The output data may include for example a temperature or power setpoint for heating elements, which may be sent directly to the heating elements or power supplies, or indirectly via a heating element control unit or other control unit such as a central control module. The output data may include for example setpoints or other control values for one or more of a water cooling system, a fan system, a wafer handling system, a wafer transfer system, as described herein.

The temperature control module 16 may comprise a processor for processing input data and/or data loaded from the memory. For example, the processor may be configured to receive a series of input data indicating layer thicknesses for a series of deposition cycles, to keep a running total of the layer thicknesses, to compare that running total with a predetermined maximum layer thickness and to initiate a temperature control protocol, or send a signal indicating that a temperature control protocol should be initiated, once the running total is greater than the predetermined maximum layer thickness.

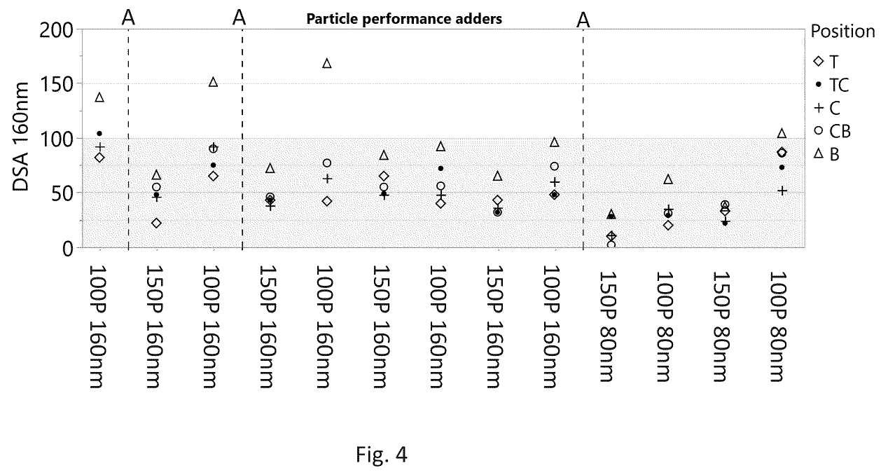

As an illustrative (non-limiting) example, referring to FIG. 4, a temperature control method according to embodiments of the present invention was carried out in a system according to embodiments of the present invention, commercially available under the trade name A412™ from ASM International N.V. of Almere, The Netherlands. A series of deposition cycles were carried out on silicon wafers. The number of wafers in the wafer boat during a deposition cycle alternated between 150 wafers (150P) and 100 wafers (100P). For the first 9 cycles, a layer of silicon nitride 160 nm thick was deposited on the wafers using DCS and ammonia as precursors. For the final 4 cycles, a layer of silicon nitride 80 nm thick was deposited on the wafers using DCS and ammonia as precursors. The maximum process temperature for each deposition cycle was 770 C.

After the first, third, and ninth deposition cycles (see dashed lines labelled ‘A’), a temperature control protocol according to embodiments of the present invention was carried out. The heating elements were turned off and the process tube temperature was allowed to decrease. When the process tube temperature reached 540 C, the process chamber was purged three times. During this time the temperature of the process chamber continued to decrease. After purging the chamber three times, the heating elements were turned on and the process tube temperature increased to 780 C. The process chamber was again purged three times while the process tube temperature was held at 780 C.

Five wafers were selected from each deposition cycle for particle contamination analysis. These are labelled T (wafer near the top of the boat), TC (wafer between the top and the middle of the boat), C (wafer near the middle of the boat), CB (wafer between the middle and the bottom of the boat), and B (wafer near the bottom of the boat). Each wafer was inspected using the SP5 wafer inspection system commercially available from KLA Corporation, California, USA. FIG. 4 shows the number of defects above 26 nm after each deposition cycle. It can be seen that after each application of the temperature control protocol, the number of defects decreases markedly.

Although illustrative embodiments of the present invention have been described above, in part with reference to the accompanying drawings, it is to be understood that the invention is not limited to these embodiments. Variations to the disclosed embodiments can be understood and effected by those skilled in the art in practicing the claimed invention, from a study of the drawings, the disclosure, and the appended claims.

Reference throughout this specification to “one embodiment” or “an embodiment” means that a particular feature, structure or characteristic described in connection with the embodiment is included in at least one embodiment of the present invention. Thus, the appearances of the phrases “in one embodiment” or “in an embodiment” in various places throughout this specification are not necessarily all referring to the same embodiment. Furthermore, it is noted that particular features, structures, or characteristics of one or more embodiments may be combined in any suitable manner to form new, not explicitly described embodiments. The subject matter of the present disclosure includes all novel and nonobvious combinations and subcombinations of the various processes, systems, and configurations, and other features, functions, acts, and/or properties disclosed herein, as well as any and all equivalents thereof.

1. A furnace system for processing substrates comprising:
a process tube arranged for receiving one or more substrates supported on a wafer boat;
one or more heating elements for heating the process tube;
a process gas flow source for providing a flow of process gas into the process tube;
a purge gas flow source for providing a flow of purge gas into the process tube; and
a temperature control module operably connected to the one or more heating elements, wherein the temperature control module is configured to perform the following steps, after a deposition cycle having a maximum process temperature has taken place in the process tube:
causing a temperature of the process tube to be decreased to a second temperature less than the maximum process temperature; and
after a purge dwell time, causing the process tube temperature to be increased to a third temperature greater than the maximum process temperature.

2. The system of claim 1, wherein causing the process tube temperature to be decreased to the second temperature comprises causing power to the heating elements to be substantially turned off.

3. The system of claim 1, wherein causing the process tube temperature to be decreased to the second temperature comprises causing a wafer boat to be inserted into the process tube.

4. The system of claim 3, wherein the wafer boat is empty.

5. The system of claim 4, wherein the wafer boat contains one or more wafers.

6. The system of claim 1, wherein causing the process tube temperature to be decreased to the second temperature comprises causing a cold gas to be flowed into the process tube.

7. The system of claim 1, wherein causing the process tube temperature to be decreased to the second temperature comprises causing a fan system to blow cold air onto the heating elements.

8. The system of claim 1, comprising a water-cooling system arranged and configured to cool the one or more heating elements, wherein causing the process tube temperature to be decreased to the second temperature comprises causing the water-cooling system to be activated.

9. The system of claim 1, wherein causing the process tube temperature to be increased to the third temperature comprises causing the process tube temperature to be ramped up, wherein the temperature ramp rate is the maximum ramp rate of which the furnace system is capable.

10. The system of claim 1, wherein the purge dwell time is chosen to be a sufficient time for the process tube to be substantially purged one time.

11. The system of claim 1, wherein the purge dwell time is chosen to be a sufficient time for the process tube to be substantially purged more than once.

12. The system of claim 1, wherein the temperature control module is configured to maintain the process tube at the third temperature for a further purge dwell time.

13. The system of claim 12, wherein the further purge dwell time is chosen to be a sufficient time for the process tube to be substantially purged one time.

14. The system of claim 12, wherein the further purge dwell time is chosen to be a sufficient time for the process tube to be substantially purged more than once.

15. The system of claim 12, wherein the temperature control module is further configured to cause the process tube temperature to be decreased to a standby temperature after the further purge dwell time.

16. The system of claim 1, wherein the second temperature is less than about 500° C.

17. The system of claim 1, wherein the third temperature is greater than about 770° C.

18. The system of claim 1, configured such that the described steps are only performed after receiving a trigger signal indicating that a predetermined number of deposition cycles has taken place, wherein the predetermined number of cycles is chosen to be a number such that a layer of material greater than 4000 Å thick is deposited.

19. The system of claim 1, wherein the deposition cycle is a process for depositing silicon nitride.

20. A method for semiconductor processing in a vertical furnace comprising:
performing at least one deposition cycle in a process tube of the vertical furnace, the at least one deposition cycle having a maximum process temperature;
causing a temperature of the process tube to be decreased to a second temperature less than the maximum process temperature;
waiting a purge dwell time; and
increasing the process tube temperature to a third temperature greater than the maximum process temperature.
